(19) United States
(12) Patent Application Publication
(10) Pub. No.: US 2021/0005799 A1
(43) Pub. Date: Jan. 7, 2021

(54) ELEMENT ASSEMBLY, AND ELEMENT AND MOUNTING SUBSTRATE ASSEMBLY

(71) Applicant: SONY SEMICONDUCTOR SOLUTIONS CORPORATION, KANAGAWA (JP)

(72) Inventors: HIROYUKI ISHIDA, KAGOSHIMA (JP); YUKIHIRO YUMISASHI, KAGOSHIMA (JP); HIDEYUKI NISHIOKA, KAGOSHIMA (JP)

(21) Appl. No.: 16/982,551

(22) PCT Filed: Mar. 6, 2019
(86) PCT No.: PCT/JP2019/008794

§ 371 Date: Sep. 19, 2020

(30) Foreign Application Priority Data
Mar. 27, 2018 (JP) 2018-059502

(51) Int. Cl. H01L 33/62; H01L 31/02

(52) U.S. Cl. CPC H01L 33/62; H01L 31/02002

(57) ABSTRACT

An element and mounting substrate assembly includes an element assembly and a mounting substrate, in which: the element assembly includes an element 20, a mold portion 30 that covers the element 20, a bonding portion 41 provided below the mold portion 30 and electrically connected to the element 20, and a heat conversion layer 50 that is formed on or above the bonding portion 41 and that generates heat on the basis of the light emitted from above the mold portion 30 through the mold portion 30; a mounting substrate 60 includes at least a substrate 61 and a connection portion 62 formed on the substrate 61; and the bonding portion 41 is bonded to the connection portion 62.

### TECHNICAL FIELD

The present disclosure relates to an element assembly, and an element and mounting substrate assembly.

### BACKGROUND ART

Various elements such as a light-emitting element and a light-receiving element are often mounted on a mounting substrate by using a solder ball, a solder bump, and a conductive adhesive (see, for example, Japanese Patent Application Laid-Open No. 2002-190661). By the way, after the elements are mounted, the elements are usually inspected. Then, in a case where a defective element is found, the defective element is removed from the mounting substrate by heating solder or the like, and a new element is mounted again on the mounting substrate.

### CITATION LIST

### Patent Document

Patent Document 1: Japanese Patent Application Laid-Open No. 2002-190661

### SUMMARY OF THE INVENTION

### Problems to be Solved by the Invention

In the technology disclosed in the patent publication described above, the defective element is heated by spot heating (heating only a portion requiring repair) by hot air, infrared rays, or the like, and the defective element is removed from the mounting substrate. However, the patent publication described above does not refer to a specific method of spot heating, and in particular, nothing is disclosed regarding a specific means for reliably removing a minute defective element from the mounting substrate.

Thus, an object of the present disclosure is to provide an element assembly having a configuration and a structure with which an element mounted on a mounting substrate can be reliably removed from the mounting substrate for repair, and an element and mounting substrate assembly including the element assembly.

### Solutions to Problems

An element assembly of the present disclosure for achieving the object described above includes:

an element;

a mold portion that covers the element;

a bonding portion provided below the mold portion and electrically connected to the element; and

a heat conversion layer that is formed on or above the bonding portion and that generates heat on the basis of light emitted from above the mold portion through the mold portion.

An element and mounting substrate assembly of the present disclosure for achieving the object described above is an element and mounting substrate assembly including an element assembly and a mounting substrate, in which:

the element assembly includes

an element,

a mold portion that covers the element,

a bonding portion provided below the mold portion and electrically connected to the element, and

a heat conversion layer that is formed on or above the bonding portion and that generates heat on the basis of light emitted from above the mold portion through the mold portion;

the mounting substrate includes at least

a substrate, and

a connection portion formed on the substrate; and

the bonding portion is bonded to the connection portion.

### BRIEF DESCRIPTION OF DRAWINGS

FIG. 1 is a schematic partial cross-sectional view in which an element and mounting substrate assembly of Example 1 is disassembled.

FIG. 2 is a diagram schematically illustrating an arrangement of some of components of the element and mounting substrate assembly of Example 1.

FIG. 3 is a schematic partial cross-sectional view in which an element and mounting substrate assembly of Example 2 is disassembled.

FIG. 4 is a schematic partial cross-sectional view in which a modification of the element and mounting substrate assembly of Example 1 is disassembled.

### MODE FOR CARRYING OUT THE INVENTION

Hereinafter, the present disclosure will be described on the basis of Examples with reference to the drawings, but the present disclosure is not limited to Examples, and various numerical values and materials in Examples are exemplifications. Note that, description will be given in the following order.

1. General description of element assembly, and element and mounting substrate assembly of the present disclosure

2. Example 1 (element assembly, and element and mounting substrate assembly of the present disclosure)

3. Example 2 (modification of Example 1)

4. Others

<General Description of Element Assembly, and Element and Mounting Substrate Assembly of the Present Disclosure>

In an element assembly of the present disclosure, or an element assembly constituting an element and mounting substrate assembly of the present disclosure (hereinafter, these element assemblies may be collectively referred to as “element assembly and the like of the present disclosure”), a mode can be made in which an orthographic image of a bonding portion is included in an orthographic image of a heat conversion layer. When an area of the orthographic image of the heat conversion layer is S₁ and an area of the orthographic image of the bonding portion is S₂, it is preferable that S₁>S₂ is satisfied.

However, this is not a limitation, and it is only required to determine the area S₁ of the orthographic image of the heat conversion layer, a thickness of the heat conversion layer, a planar shape of the heat conversion layer, the area S₂ of the orthographic image of the bonding portion, a thickness (height) of the bonding portion, a planar shape of the bonding portion, and the like on the basis of various tests and simulations so that heat generated by heat generation of the heat conversion layer is transferred to the bonding portion as uniformly as possible. Furthermore, when an element is removed from a mounting substrate, when the heat conversion layer is irradiated with light from above a mold portion through the mold portion, heat is generated in the heat conversion layer, and as a result, the bonding portion bonded to a connection portion is melted, but it is necessary to suck and remove the melted bonding portion. Air is caused to flow when the bonding portion is sucked and removed; however, it is only required to determine the area S₁ of the orthographic image of the heat conversion layer, the thickness of the heat conversion layer, the planar shape of the heat conversion layer, the area S₂ of the orthographic image of the bonding portion, the thickness (height) of the bonding portion, the planar shape of the bonding portion, and the like on the basis of various tests and simulations so that the flow of the air does not hinder the transfer of the heat generated by the heat generation of the heat conversion layer to the bonding portion.

In the element assembly and the like of the present disclosure including the preferable mode described above, a mode can be made in which the heat conversion layer includes at least one material selected from titanium, chromium, or nickel.

Moreover, in the element assembly and the like of the present disclosure including the various preferable modes described above, a mode can be made in which the heat conversion layer also serves as a wiring line that electrically connects the element and the bonding portion together. To electrically connect the element and the bonding portion together, a wiring line may be provided including a conductive material such as aluminum, an aluminum alloy, copper, or a copper alloy, for example.

Moreover, in the element assembly and the like of the present disclosure including the various preferable modes described above, the heat conversion layer is preferably arranged at a level lower than the element. That is, when viewed in the vertical direction, from the bottom (that is, from the mounting substrate side), the bonding portion, the heat conversion layer, the element, and the mold portion are arranged.

Moreover, in the element assembly and the like of the present disclosure including the various preferable modes described above, the mold portion is preferably transparent to light having a wavelength of less than or equal to 1.0×10⁻⁶ m, and in this case, the wavelength of the light is more preferably 8×10⁻⁷ m to 1.0×10⁻⁶ m. Note that, examples of a source of such light include a laser light source.

Moreover, in the element assembly and the like of the present disclosure including the various preferable modes described above, a mode can be made in which the mold portion includes a polyimide resin or acrylic resin having photosensitivity.

Moreover, in the element assembly and the like of the present disclosure including the various preferable modes described above, a mode can be made in which the bonding portion includes solder (specifically, a solder ball or a solder bump) or a conductive adhesive.

Moreover, in the element assembly and the like of the present disclosure including the various preferable modes described above, a thermal resistance value Rₜₕ₋₁ of the heat conversion layer is preferably higher than a thermal resistance value Rₜₕ₋₂ of the bonding portion.

Moreover, in the element assembly and the like of the present disclosure including the various preferable modes described above, a mode can be made in which the element includes: a light-emitting element such as a light emitting diode (LED), a semiconductor laser element, or an electroluminescence (EL) element; a light-receiving element; a light reflection element; or an optical modulation element, and it is also possible to exemplify a MEMS, a temperature sensor, a humidity sensor, a pressure sensor, and the like. Alternatively, a mode can be made in which the element includes an active element, an active component, a passive element, and a passive component. For example, an optical sensor, an infrared sensor, and a light-receiving element that constitutes an imaging element (image sensor) can include a photodiode having a known configuration and structure.

The element assembly and the like of the present disclosure may include one element, or may include a plurality of elements. It is preferable that one mold portion covers the entire of the plurality of elements in the latter case, and that the heat conversion layer is provided having an optimum shape, area, and the like for each element in the latter case. The number of bonding portions is determined depending on the number of elements and structures of the elements included in the element assembly and the like of the present disclosure.

A pad portion is preferably provided for connecting the element and the wiring line together. A mode can be made in which the pad portion, the heat conversion layer, the wiring line, and the bonding portion are formed on a relay substrate (interposer). The pad portion can include, for example, a conductive layer formed on the basis of a copper plating method, various physical vapor deposition methods (PVD methods), or various chemical vapor deposition methods (CVD methods). Examples of the relay substrate (interposer) include a glass substrate, a quartz substrate, a silicon substrate, a rigid printed wiring board, and a flexible printed wiring board. That is, it is sufficient that the bonding portion is formed on a first surface of the relay substrate, the heat conversion layer and the pad portion are formed on a side of a second surface facing the first surface, and the pad portion and the bonding portion are electrically connected together by the wiring line. The wiring line may be formed on the first surface of the relay substrate, or may be formed on the side of the second surface facing the first surface.

To form the heat conversion layer, the pad portion, and the like on the side of the second surface of the relay substrate, it is only required to form an insulating layer on the side of the second surface of the relay substrate. Examples of a material for forming the insulating layer include silicon oxide (SiO_{X}), silicon nitride (SiN_{Y}), silicon oxynitride (SiO_{X}N_{Y}), tantalum oxide (Ta₂O₅), zirconium oxide (ZrO₂), aluminum oxide (Al₂O₃), aluminum nitride (AlN), titanium oxide (TiO₂), magnesium oxide (MgO), chromium oxide (CrOₓ), vanadium oxide (VOₓ), and tantalum nitride (TaN). The insulating layer can be formed by various PVD methods or various CVD methods depending on the material used. Furthermore, patterning can be performed on the basis of a combination of lithography technology and etching technology. An insulating material layer described later can also be formed by a similar method using a material similar to the insulating layer. Furthermore, in addition to the above, examples of the material for forming the insulating layer include a dielectric multilayer film (for example, a dielectric multilayer film having a structure in which a low refractive index thin film such as SiO₂ and a high refractive index thin film such as TiO₂ or Ta₂O₅ are alternately laminated), or a laminated structure of SiO₂ layer/Si layer (the SiO₂ layer is the lower layer and the Si layer is the upper layer).

Examples of the mounting substrate include a glass substrate, a quartz substrate, a silicon substrate, a polyimide substrate, and an acrylic substrate of which the connection portion including a copper foil or a copper plating layer is formed on the surface, include a rigid printed wiring board and a flexible printed wiring board of which the connection portion including the copper foil or the copper plating layer is formed on the surface, and include a single-sided substrate, a double-sided substrate, a multilayer substrate, and a build-up substrate. The configuration of a base material forming a rigid printed circuit board is essentially arbitrary, and examples thereof include a combination of paper/phenolic resin, paper/epoxy resin, glass cloth/epoxy resin, glass nonwoven fabric/epoxy resin, glass cloth/glass nonwoven fabric/epoxy resin, synthetic fiber/epoxy resin, glass cloth/polyimide resin, glass cloth/modified polyimide resin, glass cloth/epoxy modified polyimide resin, glass cloth/bismaleimide/triazine/epoxy resin, glass cloth/fluorine resin, glass cloth/polyphenylene oxide (PPO) resin, and glass cloth/polyphenylene ether (PPE) resin.

In the mounting substrate, a surface on which the connection portion is formed is preferably covered with an insulating material film. Examples of a material for forming the insulating material film include an organic material (specifically, for example, an epoxy resin, an acrylic resin, a polyimide resin, a silicone resin, or the like) or an inorganic material (specifically, for example, silicon oxide, silicon nitride, aluminum oxide, or the like). The insulating material film functions as a protective film, and furthermore, also functions as a planarizing film.

### Example 1

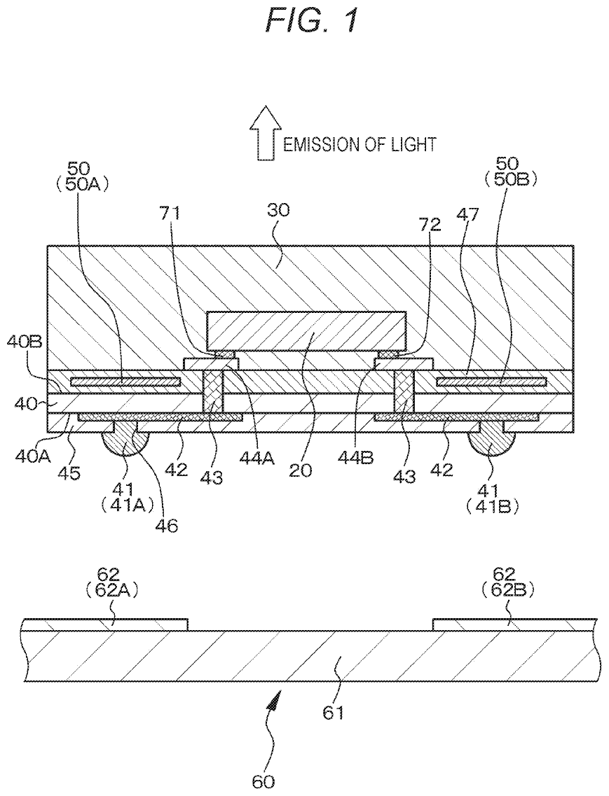

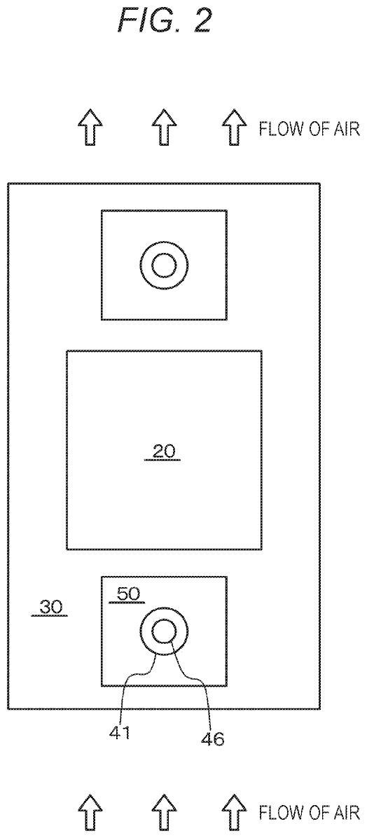

Example 1 relates to the element assembly, and the element and mounting substrate assembly of the present disclosure. FIG. 1 illustrates a schematic partial cross-sectional view in which the element and mounting substrate of the present disclosure of Example 1 is disassembled, and FIG. 2 schematically illustrates an arrangement of some of components of the element and mounting substrate assembly of Example 1.

An element assembly of Example 1 includes:

an element (functional element) 20;

a mold portion 30 that covers the element 20;

a bonding portion 41 provided below the mold portion 30 and electrically connected to the element 20; and

a heat conversion layer 50 that is formed on or above the bonding portion 41 and that generates heat on the basis of light emitted from above the mold portion 30 through the mold portion 30.

Furthermore, the element and mounting substrate assembly of Example 1 includes an element assembly (specifically, the element assembly of Example 1) and a mounting substrate 60, and the mounting substrate 60 includes at least a substrate 61, and a connection portion 62 formed on the substrate 61. Then, the bonding portion 41 is bonded to the connection portion 62.

Note that, in the illustrated example, the heat conversion layers 50 (50A, 50B) are formed above the respective bonding portions 41 (41A, 41B). Furthermore, the heat conversion layers (50A, 50B) are arranged at a level lower than the element 20. That is, when viewed in the vertical direction, from the bottom (that is, from the mounting substrate side), the bonding portions 41 (41A, 41B), the heat conversion layers 50 (50A, 50B), the element 20, and the mold portion 30 are arranged. In Example 1, the element 20 includes a light-emitting element, specifically, for example, an LED.

Then, an orthographic image of the bonding portion 41 (41A, 41B) is included in an orthographic image of the heat conversion layer 50 (50A, 50B). That is, when an area of the orthographic image of the heat conversion layer 50 (50A, 50B) is S₁ and an area of the orthographic image 41 (41A, 41B) of the bonding portion is S₂, S₁>S₂ is satisfied.

Furthermore, the heat conversion layer 50 (50A, 50B) includes titanium (Ti) having a thickness of 0.1 μm. The mold portion 30 is transparent to light having a wavelength of less than or equal to 1.0×10⁻⁶ m. Here, the wavelength of the light is preferably 8×10⁻⁷ m to 1.0×10⁻⁶ m. Specific examples of a light source include a laser light source that emits near infrared rays having a wavelength of 800 nm. The absorption rate of light having a wavelength of 800 nm of Ti is 46%. The mold portion 30 includes a polyimide resin having photosensitivity. The bonding portion 41 (41A, 41B) includes solder (specifically, a solder bump) and is bonded to the connection portion 62 (62A, 62B) including a wiring line 42.

Then, the thermal resistance value Rₜₕ₋₁ of the heat conversion layer 50 (50A, 50B) is preferably higher than the thermal resistance value Rₜₕ₋₂ of the solder, specifically, the solder bump) forming the bonding portion 41 (41A, 41B).

Pad portions 44A and 44B are provided to connect the element 20 and the wiring line 42 together. In the element 20, a first connection terminal 71 is connected to the first pad portion 44A, and a second connection terminal 72 is connected to the second pad portion 44B. The pad portions 44A and 44B, the heat conversion layer 50 (50A, 50B), the wiring line 42, and the bonding portion 41 (41A, 41B) are formed on a relay substrate (interposer) 40. The pad portions 44A and 44B are formed on an insulating layer 47. The pad portions 44A and 44B include, for example, a conductive layer formed on the basis of a copper plating method. The bonding portion 41 (41A, 41B) and the wiring line 42 are formed on a first surface 40A of the relay substrate (a surface on an opposite side from a light emission side), and the heat conversion layer 50 (50A, 50B) and the pad portions 44A and 44B are formed on a side (a surface on the same side as the light emission side) of a second surface 40B facing the first surface 40A. Each of the pad portions 44A and 44B, and the bonding portion 41 (41A, 41B) are electrically connected together by a contact hole 43 and the wiring line 42. An insulating material layer 45 including an opening 46 is formed on the first surface 40A of the relay substrate 40, and the bonding portion 41 (41A, 41B) is formed over a range from the wiring line 42 exposed at the bottom of the opening 46 to the opening 46 and part of the insulating material layer 45. Furthermore, the insulating layer 47 including, for example, TEOS is formed on the second surface 40B of the relay substrate 40, and the heat conversion layer 50 (50A, 50B) is formed between layers of the insulating layer 47.

Examples of the mounting substrate 60 include the glass substrate 61 of which the connection portion 62 (the first connection portion 62A and the second connection portion 62B) including a copper foil or a copper plating layer is formed on the surface. The first connection portion 62A is connected to a first wiring line, and the second connection portion 62B is connected to a second wiring line. Each of a plurality of the first wiring lines has a strip shape as a whole, and extends in a first direction, and each of a plurality of the second wiring lines has a strip shape as a whole, and extends in a second direction different from the first direction (for example, in a direction orthogonal to the first direction). Illustration of the first wiring lines and the second wiring lines is omitted. The mounting substrate 60 can be formed by a known method.

When the element 20 is removed from the mounting substrate 60 for repair, when the heat conversion layer 50 (50A, 50B) is irradiated with light from above the mold portion 30 through the mold portion 30, heat is generated in the heat conversion layer (50A, 50B), and as a result, the bonding portion 41 (41A, 41B) bonded to the connection portions 62A and 62B is melted. The melted bonding portion 41 (41A, 41B) is sucked and removed. At this time, as schematically illustrated in FIG. 2, an air flow occurs; however, it is only required to determine the area S₁ of the orthographic image of the heat conversion layer, the thickness of the heat conversion layer, the planar shape of the heat conversion layer, the area S₂ of the orthographic image of the bonding portion, the thickness (height) of the bonding portion, the planar shape of the bonding portion, and the like on the basis of various tests and simulations so that the air flow does not hinder transfer of the heat generated by the heat generation of the heat conversion layer 50 (50A, 50B) to the bonding portion 41 (41A, 41B).

In the element assembly, and the element and mounting substrate assembly of Example 1, since the heat conversion layer is provided, even if the mold portion is transparent to light with which the mold portion is irradiated when the element (for example, the light emitting element) is removed from the mounting substrate, heat is uniformly generated in the heat conversion layer when the heat conversion layer is irradiated with the light from above the mold portion through the mold portion, and as a result, the bonding portion bonded to the connection portion is melted uniformly, so that there is no possibility that the bonding portion remains when the bonding portion is removed, and the element (for example, the light-emitting element) mounted on the mounting substrate can be reliably and easily removed from the mounting substrate for repair, and it is possible to reliably avoid occurrence various problems (for example, a problem that it is difficult to remount a new element) as a result of the remaining bonding portion.

### Example 2

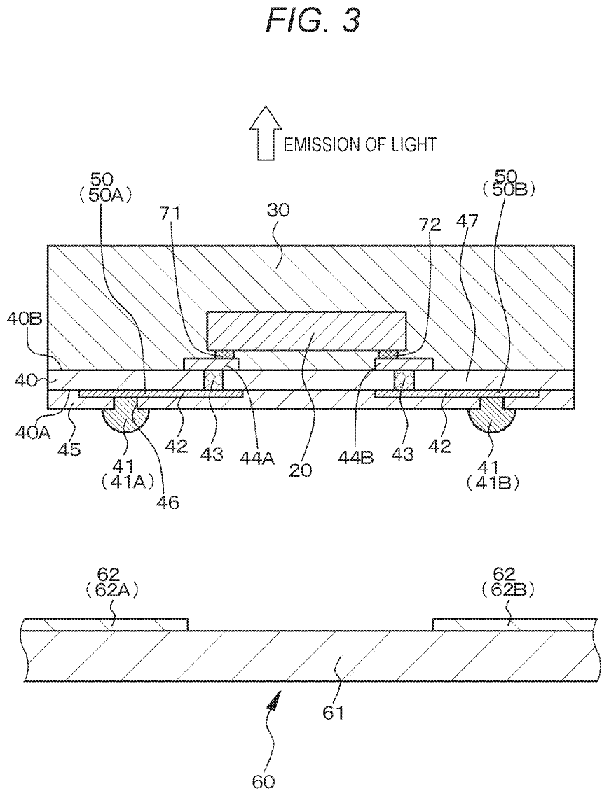

Example 2 is a modification of Example 1. As illustrated in FIG. 3 that is a schematic partial cross-sectional view in which an element and mounting substrate assembly of Example 2 is disassembled, in Example 2, the heat conversion layer 50 (50A, 50B) also serves as the wiring line 42 that electrically connects the element and the bonding portion 41 (41A, 41B) together. Specifically, to connect the element 20 and the wiring line 42 together, the pad portions 44A and 44B are formed on the second surface 40B of the relay substrate (interposer) 40. Furthermore, the wiring line 42 that also serves as the bonding portion 41 (41A, 41B) and the heat conversion layer 50 (50A, 50B) is formed on the first surface 40A of the relay substrate 40. The heat conversion layers 50 (50A, 50B) are formed on the respective bonding portions 41 (41A, 41B). Each of the pad portions 44A and 44B, and the bonding portion 41 (41A, 41B) are electrically connected together by a contact hole 43 and the wiring line 42. An insulating material layer 45 including an opening 46 is formed on the first surface 40A of the relay substrate 40, and the bonding portion 41 (41A, 41B) is formed over a range from the wiring line 42 exposed at the bottom of the opening 46 to the opening 46 and part of the insulating material layer 45.

Except for the points described above, the element assembly, and the element and mounting substrate assembly of Example 2 can be configured similarly to the element assembly, and the element and mounting substrate assembly described in Example 1, and thus the detailed description is omitted.

Although the present disclosure has been described above on the basis of preferable Examples, the present disclosure is not limited to these Examples. The configurations and structures of the element assemblies, and the element and mounting substrate assemblies described in Examples are exemplary, and members, materials, and the like constituting these are also examples, and can be appropriately changed.

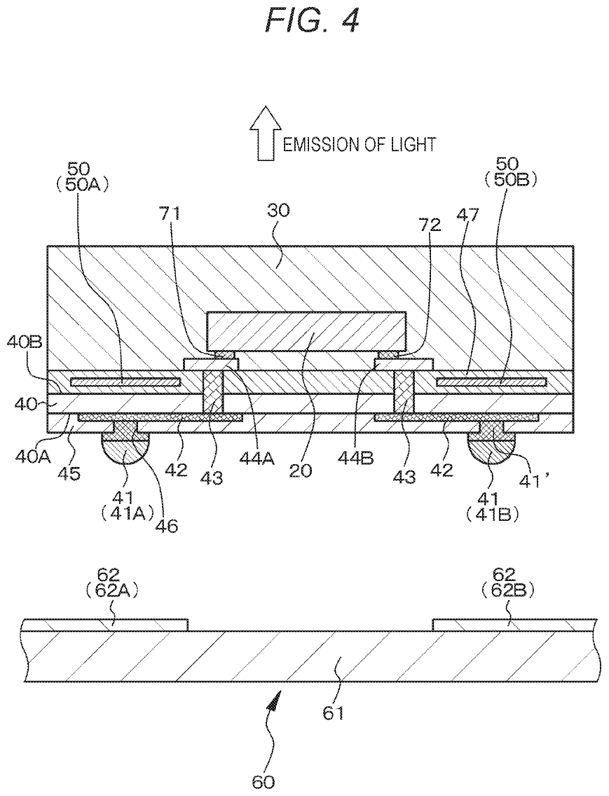

As illustrated in FIG. 4, the insulating material layer 45 including the opening 46 may be formed on the first surface 40A of the relay substrate 40, and a bonding portion pad 41′ may be formed over a range from the wiring line 42 exposed at the bottom of the opening 46 to the opening 46 and part of the insulating material layer 45, and the bonding portion 41 (41A, 41B) including, for example, a solder bump may be formed on the bonding portion pad 41′. Note that, such a structure can also be applied to Example 2.

Note that, the present disclosure can also adopt the following configurations.

### [A01]<<Element Assembly>>

An element assembly including:

an element;

a mold portion that covers the element;

a bonding portion provided below the mold portion and electrically connected to the element; and

a heat conversion layer that is formed on or above the bonding portion and that generates heat on the basis of light emitted from above the mold portion through the mold portion.

[A02] The element assembly according to [A01], in which an orthographic image of the bonding portion is included in an orthographic image of the heat conversion layer.
[A03] The element assembly according to [A01] or [A02], in which the heat conversion layer includes at least one material selected from titanium, chromium, or nickel.
[A04] The element assembly according to any one of [A01] to [A03], in which the heat conversion layer also serves as a wiring line that electrically connects the element and the bonding portion together.
[A05] The element assembly according to any one of [A01] to [A04], in which the heat conversion layer is arranged at a level lower than the element.
[A06] The element assembly according to any one of [A01] to [A05], in which the mold portion is transparent to light having a wavelength of less than or equal to 1.0×10⁻⁶ m.
[A07] The element assembly according to [A06], in which the wavelength of the light is 8×10⁻⁷ m to 1.0×10⁻⁶ m.
[A08] The element assembly according to any one of [A01] to [A07], in which the mold portion includes a polyimide resin having photosensitivity.
[A09] The element assembly according to any one of [A01] to [A08], in which a part of the bonding portion includes solder or a conductive adhesive.
[A10] The element assembly according to any one of [A01] to [A09], in which a thermal resistance value Rₜₕ₋₁ of the heat conversion layer is higher than a thermal resistance value Rₜₕ₋₂ of the bonding portion.
[A11] The element assembly according to any one of [A01] to [A10], in which the element includes a light-receiving element, a light-emitting element, a light reflection element, or an optical modulation element.

### [B01]<<Element and Mounting Substrate Assembly>>

An element and mounting substrate assembly including an element assembly and a mounting substrate, in which:

the element assembly includes

an element,

a mold portion that covers the element,

a bonding portion provided below the mold portion and electrically connected to the element, and

a heat conversion layer that is formed on or above the bonding portion and that generates heat on the basis of light emitted from above the mold portion through the mold portion;

the mounting substrate includes at least

a substrate, and

a connection portion formed on the substrate; and

the bonding portion is bonded to the connection portion.

[B02] The element and mounting substrate assembly according to [B01], in which an orthographic image of the bonding portion is included in an orthographic image of the heat conversion layer.
[B03] The element and mounting substrate assembly according to [B01] or [B02], in which the heat conversion layer includes at least one material selected from titanium, chromium, or nickel.
[B04] The element and mounting substrate assembly according to any one of [B01] to [B03], in which the heat conversion layer also serves as a wiring line that electrically connects the element and the bonding portion together.
[B05] The element and mounting substrate assembly according to any one of [B01] to [B04], in which the heat conversion layer is arranged at a level lower than the element.
[B06] The element and mounting substrate assembly according to any one of [B01] to [B05], in which the mold portion is transparent to light having a wavelength of less than or equal to 1.0×10⁻⁶ m.
[B07] The element and mounting substrate assembly according to [B06], in which the wavelength of the light is 8×10⁻⁷ m to 1.0×10⁻⁶ m.
[B08] The mold portion is the element and mounting substrate assembly according to any one of [B01] to [B07], in which the mold portion includes a polyimide resin having photosensitivity.
[B09] The element and mounting substrate assembly according to any one of [B01] to [B08], in which a part of the bonding portion includes solder or a conductive adhesive.
[B10] The element and mounting substrate assembly according to any one of [B01] to [B09], in which a thermal resistance value Rₜₕ₋₁ of the heat conversion layer is higher than a thermal resistance value Rₜₕ₋₂ of the bonding portion.
[B11] The element and mounting substrate assembly according to any one of [B01] to [B10], in which the element includes a light-receiving element, a light-emitting element, a light reflection element, or an optical modulation element.

### REFERENCE SIGNS LIST

20 Element
30 Mold portion
40 Relay substrate (interposer)
41, 41A, 41B Bonding portion
42 Wiring line
43 Contact hole
44A, 44B Pad portion
45 Insulating material layer
46 Opening
47 Insulating layer
50, 50A, 50B Heat conversion layer
60 Mounting substrate
61 Substrate
62, 62A, 62B Connection portion
71, 72 Connection terminal

1. An element assembly comprising:
an element;
a mold portion that covers the element;
a bonding portion provided below the mold portion and electrically connected to the element; and
a heat conversion layer that is formed on or above the bonding portion and that generates heat on a basis of light emitted from above the mold portion through the mold portion.

2. The element assembly according to claim 1, wherein an orthographic image of the bonding portion is included in an orthographic image of the heat conversion layer.

3. The element assembly according to claim 1, wherein the heat conversion layer includes at least one material selected from titanium, chromium, or nickel.

4. The element assembly according to claim 1, wherein the heat conversion layer also serves as a wiring line that electrically connects the element and the bonding portion together.

5. The element assembly according to claim 1, wherein the heat conversion layer is arranged at a level lower than the element.

6. The element assembly according to claim 1, wherein the mold portion is transparent to light having a wavelength of less than or equal to 1.0×10⁻⁶ m.

7. The element assembly according to claim 6, wherein the wavelength of the light is 8×10⁻⁷ m to 1.0×10⁻⁶ m.

8. The element assembly according to claim 1, wherein the mold portion includes a polyimide resin having photosensitivity.

9. The element assembly according to claim 1, wherein a part of the bonding portion includes solder or a conductive adhesive.

10. The element assembly according to claim 1, wherein a thermal resistance value Rₜₕ₋₁ of the heat conversion layer is higher than a thermal resistance value Rₜₕ₋₂ of the bonding portion.

11. The element assembly according to claim 1, wherein the element includes a light-receiving element, a light-emitting element, a light reflection element, or an optical modulation element.

12. An element and mounting substrate assembly comprising an element assembly and a mounting substrate, wherein:
the element assembly includes
an element,
a mold portion that covers the element,
a bonding portion provided below the mold portion and electrically connected to the element, and
a heat conversion layer that is formed on or above the bonding portion and that generates heat on a basis of light emitted from above the mold portion through the mold portion;
the mounting substrate includes at least
a substrate, and
a connection portion formed on the substrate; and
the bonding portion is bonded to the connection portion.
